(19) United States
(12) Patent Application Publication
(10) Pub. No.: US 2015/0106673 A1
(43) Pub. Date: Apr. 16, 2015

(54) METHOD AND APPARATUS FOR ON-THE-FLY MEMORY CHANNEL BUILT-IN-SELF-TEST

(71) Applicants: Jung Chi Huang, Changhua County (TW); Wen Hsuan Hu, Hsinchu County (TW); Chao Yu Chen, Hsinchu City (TW)

(72) Inventors: Jung Chi Huang, Changhua County (TW); Wen Hsuan Hu, Hsinchu County (TW); Chao Yu Chen, Hsinchu City (TW)

(73) Assignees: TAIWAN SEMICONDUCTOR MANUFACTURING COMPANY LTD., HSINCHU (TW); GLOBAL UNICHIP CORP., HSINCHU (TW)

(21) Appl. No.: 14/054,856

(22) Filed: Oct. 16, 2013

(51) Int. Cl. G01R 31/3187

(52) U.S. Cl. CPC G01R 31/3187
USPC 714/733

(57) ABSTRACT

The present invention discloses a memory channel bridge with a BIST module; and the memory channel bridge interfaces other channels in a SOC to access a memory module. During a DFT test, SOC memory channels and the BIST access the memory module concurrently by using an arbiter in the memory channel bridge to arbitrate the traffics from the SOC memory channels and the BIST to ensure the correctness and completeness of the whole design.

### BACKGROUND OF THE INVENTION

1. Field of the Invention

The invention relates in general to a memory channel bridge and, in particular, to a memory channel bridge with BIST (Built-In-Self-Test) capability.

2. Description of the Prior Art

In a conventional SOC (system-on-chip) design, CPU, application engines and IO interfaces will access the DDR DRAM resource through a memory channel bridge IP (Intellectual Property). In such IP, a memory IP built-in self test is always provided to do production test of memory IP subsystem.

Conventionally, as shown in FIG. 1, in a system-on-chip (SOC) 100, a memory channel bridge 105 is used to bridge the traffics from CPU 102, Application Engine 103 and I/O Interface DMA 104 to system memory such as DDR DRAM memory module 101 through a DDR controller IP 107 and DDR physical interface 106. A DFT (Design-For-Test) memory BIST (Built-In-Self-Test) module 108 is contained in the memory channel bridge 105 for testing the DDR DRAM memory module 101. The DFT memory BIST can test memory controller IP, memory PHY IP with external DRAM. However, the normal user function part of the SOC, for example, the data path from the Application Engine 103 or I/O Interface DMA 104 to the DDR controller IP 107 will be blocked when the DFT memory BIST is performing the test. As shown in FIG. 2 which illustrates a diagram for a conventional DFT (Design-For-Test) mechanism of memory channel bridge IP 105 with a DDR user interface module 110 to connect to the other part of SOC 112. The data path from the DDR user interface module 110 to the DDR controller core 111 is blocked, as indicated by a symbol X 113, when the DFT memory BIST 108 is running Consequently, the conventional DFT memory BIST may not be enough to cover SOC IR drop worst condition or DDR bus worst case SSC

(Spread Spectrum Clock) condition because the results of the DFT memory BIST tests are hard to be correlated to the SOC functional tests. As a result, even if the BIST passes the test, the SOC functional test may still fail.

FIG. 3 illustrates the conventional way to perform BIST and SOC functional tests. Co-relation data collection is needed between the results of the actual SOC functional tests 301 on a system module and the scan voltage and temperature criteria of memory BIST test conditions 302. Consequently, it is time consuming to co-relate such huge amount of test data and still not able to get robust co-relations between the SOC functional test and the BIST test especially when the design of the SOC is marginal.

Therefore, what is needed is a new way to perform a DFT test including memory BIST and other SOC functional tests to ensure the correctness and completeness of the whole design.

### SUMMARY OF THE INVENTION

One purpose of this invention is to provide a way to perform a DFT test including memory BIST and other SOC functional tests to ensure the correctness and completeness of the whole design. The memory BIST function and other SOC memory channel functions can be turned on simultaneously while the BIST is testing a memory module. SOC condition can thus be emulated during the memory BIST is running During a DFT test, SOC function traffics and memory BIST traffics are arbitrated by an arbitration mechanism.

In one embodiment, a memory channel bridge is disclosed. The memory channel bridge comprises: a first interface, for connecting to a first functional module; a BIST module coupling to the first interface, for testing the first functional module; a second interface, for connecting to a second functional module; and an arbiter coupled to the BIST module and the second interface, for arbitrating between the BIST module and the second functional module to access the first functional module; wherein the second functional module and the BIST module access the first functional module concurrently while the first functional module is being tested by the BIST module. In one embodiment, the first functional module comprises a memory module and a memory controller to control the memory module. In one embodiment, the first functional module is a memory module; and the memory channel bridge further comprises a memory controller coupled to the arbiter and the first interface to control the memory module.

In one embodiment, a system-on-chip (SOC) comprising a memory channel bridge is disclosed. The SOC comprises: a first interface, for connecting to a memory module; a BIST module coupling to the first interface, for testing the memory module; a second functional module; an arbiter coupled to the BIST module and the second functional module, for arbitrating between the BIST module and the second functional module to access the memory module; and a memory controller coupled to the arbiter and the first interface, for controlling the memory module; wherein the BIST module and the second functional module access the memory module through the arbiter and the memory controller concurrently while the memory module is being tested by the BIST module.

In one embodiment, a method of performing a DFT test is disclosed. The method comprises the steps of: providing a first functional module; providing a BIST module coupling to first functional module to test the first functional module; providing a second functional module coupling to first functional module to access the first functional module; and arbitrating traffics from the BIST module and the second functional module to access the first functional module, wherein the second functional module and the BIST module access the first functional module concurrently while the first functional module is being tested by the BIST module.

With the brief description of drawings and detailed description of embodiment disclosed below, advantage, scope, and technical details of this invention are easy to be understood.

### BRIEF DESCRIPTION OF DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 illustrates a diagram for a conventional DFT mechanism of memory channel bridge IP;

FIG. 2 illustrates a diagram for a conventional DFT mechanism of memory channel bridge IP with user traffic interface;

FIG. 3 illustrates the conventional way to perform BIST and SOC functional tests;

FIG. 4A-4C illustrates a diagram of a memory channel bridge according to one embodiment of current invention;

FIG. 5A-5B illustrates a diagram of a SOC with a memory channel bridge according to one embodiment of current invention; and

FIG. 6 illustrates a flow chart of for performing a DFT test.

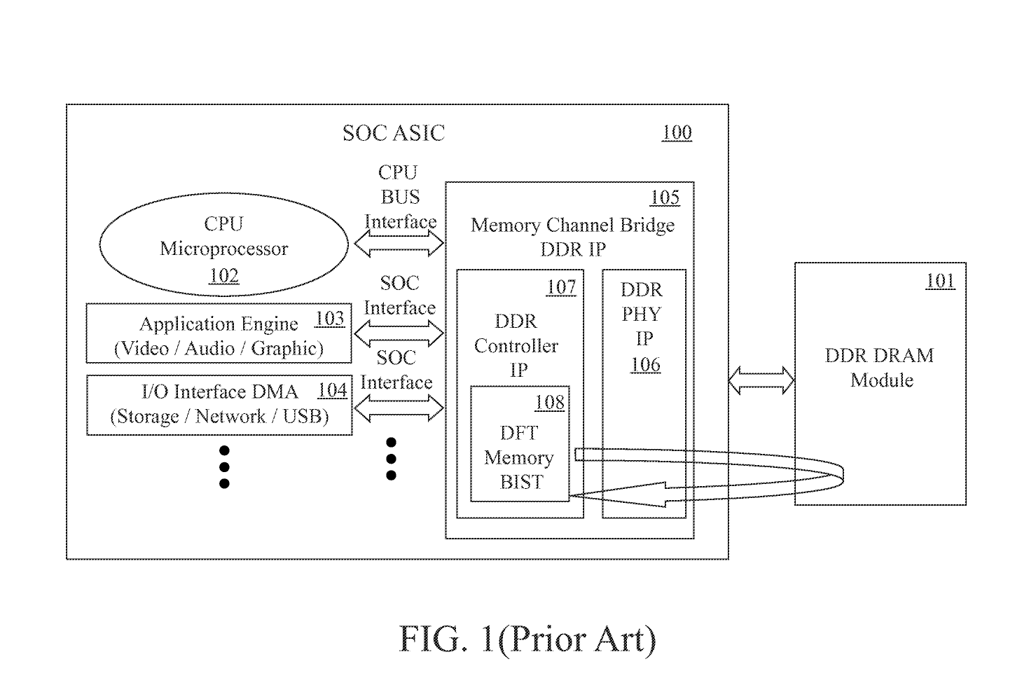

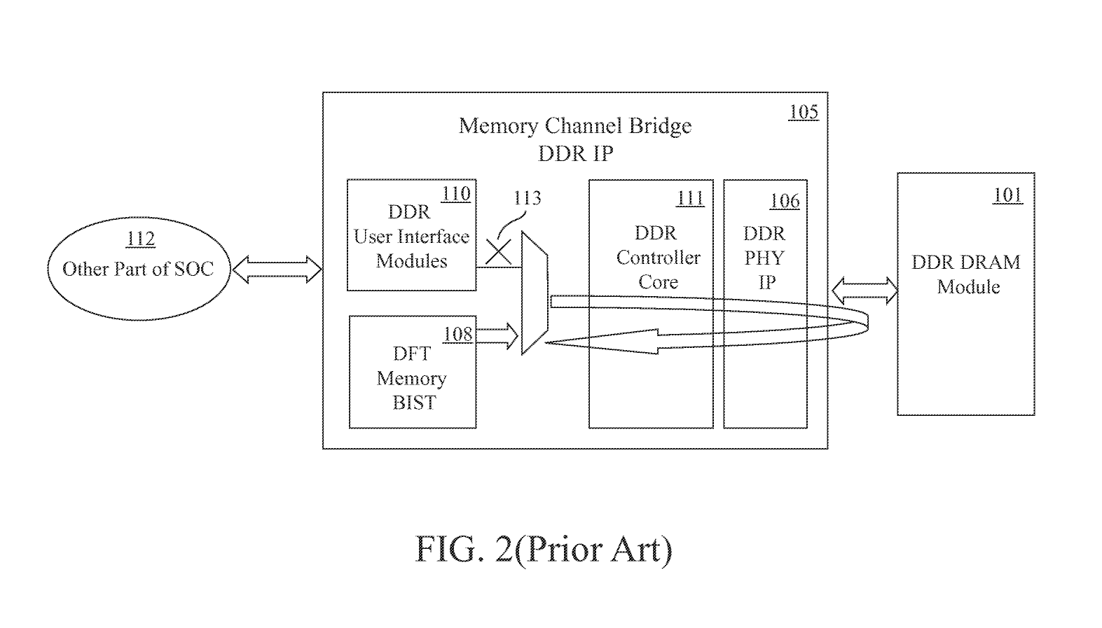

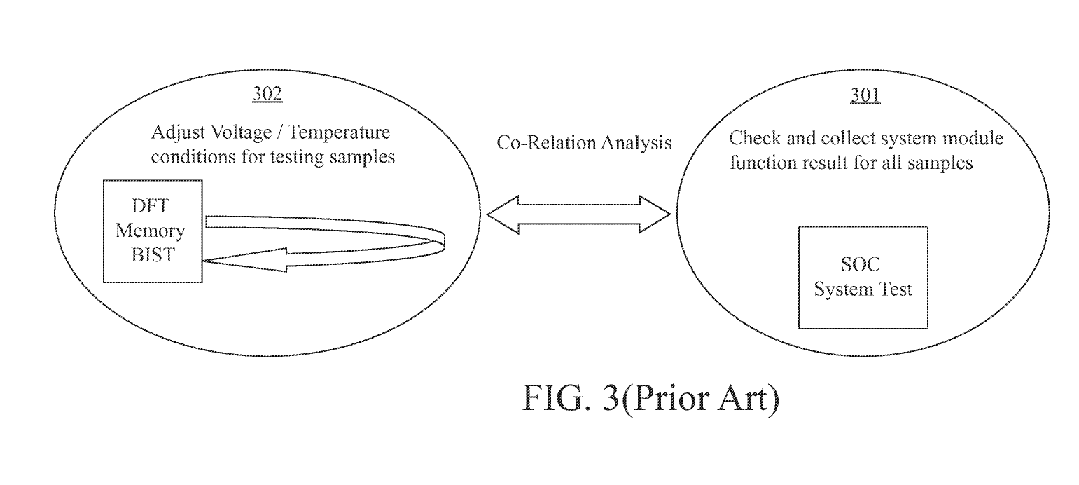

### DETAILED DESCRIPTION OF EMBODIMENT

The detailed explanation of the present invention is described as following. The described preferred embodiments are presented for purposes of illustrations and description, and they are not intended to limit the scope of the present invention.

The present invention discloses a channel bridge with a BIST function to test a functional module, wherein the channel bridge interfaces other SOC memory channels to access the functional module. During DFT test, SOC channels and the BIST can be turned on simultaneously. SOC function traffics and memory BIST traffics are arbitrated by an arbitration mechanism. Please note that the channel bridge described above is not limited to memory access, for example, it can be used for testing and accessing an Ethernet module, a USB module or other functional modules.

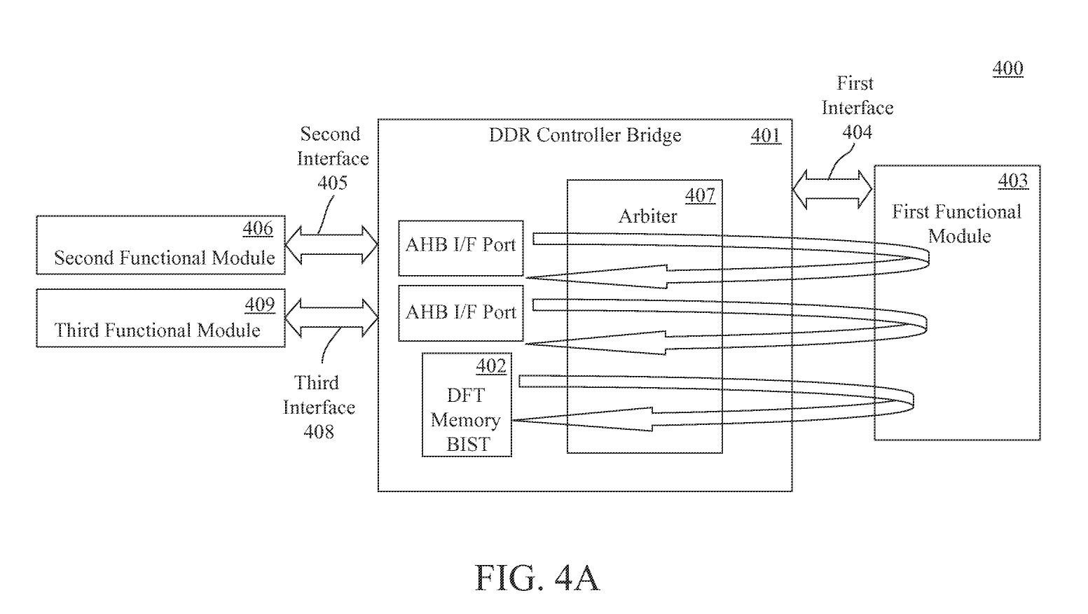

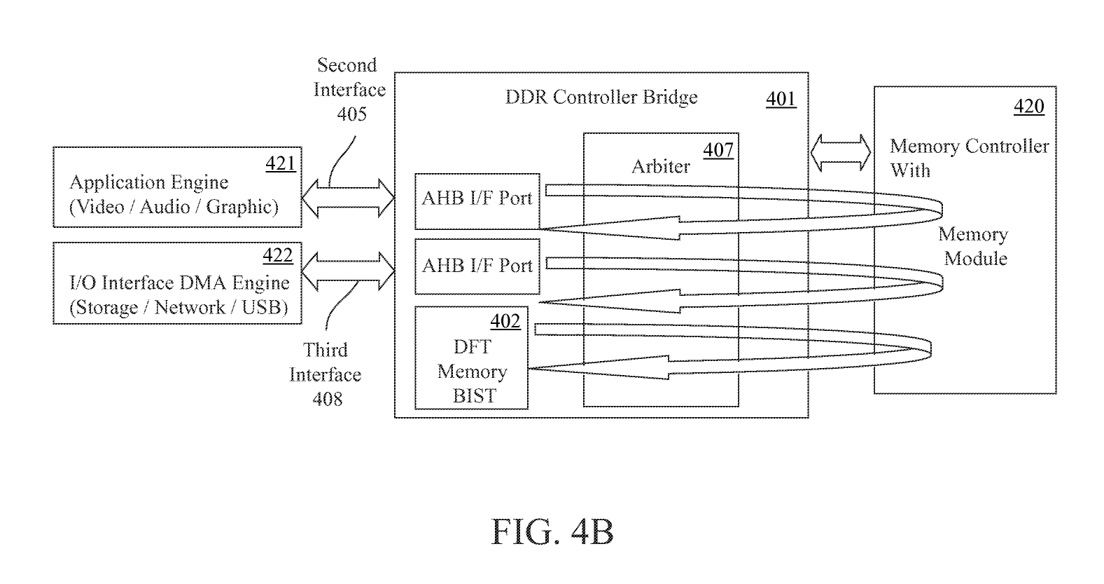

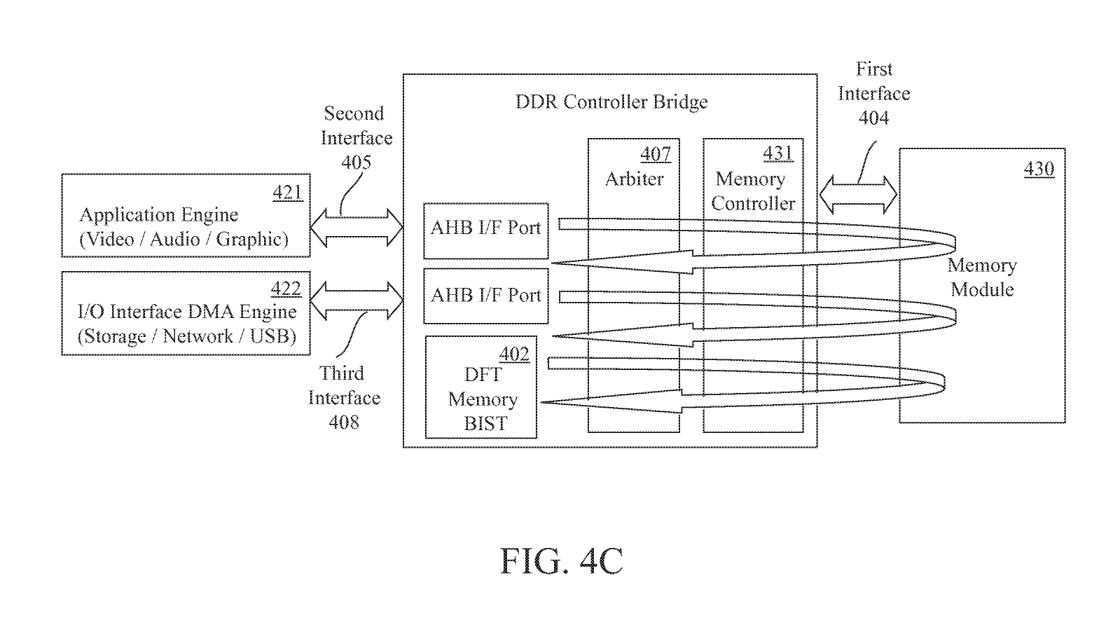

In one embodiment, please refer to FIG. 4A which illustrates a diagram 400 of a memory channel bridge according to one embodiment of current invention. As shown in FIG. 4A, a memory channel bridge 401 which comprises a BIST module 402 for testing a functional module 403; a first interface 404, for connecting to a first functional module 403; a BIST module 402 coupling to the first interface 404, for testing the first functional module 403; a second interface 405, for connecting to a second functional module 406; and an arbiter 407 coupled to the BIST module 402 and the second interface 405, for arbitrating between the BIST module 402 and the second functional module 406 to access the first functional module 403; wherein the second functional module 406 and the BIST module 402 access the first functional module 403 concurrently while the first functional module 403 is being tested by the BIST module 402 during a DFT test. Please note that during a DFT test, memory BIST test result can be checked and the SOC functional test result can be either checked or ignored based on the features of the DFT.

In one embodiment, the memory channel bridge further comprising a third interface 408 for connecting to a third functional module 409, wherein the arbiter 407 is further coupled to the third interface 408 to arbitrate among the BIST module 402, the second functional module 406 and the third functional module 409 to access the first functional module 403, wherein the BIST module 402, the second functional module 406 and the third functional module 409 access the first functional module 403 concurrently while the first functional module 403 is being tested by the BIST module 402 during a DFT test. There can be more functional modules attached to the memory channel bridge to access the memory module depending on application needs. Please note that during a DFT test, the memory BIST test result can be checked and the SOC functional test result can be either checked or ignored based on the features of the DFT.

In one embodiment, as shown in FIG. 4B, the first functional module comprises a memory module and a memory controller to control the memory module 420. The second functional module is an application engine (Video/Audio/Graphic) 421 having a first DMA interface connecting to the second interface 405 and the third functional module is an I/O Interface DMA engine (Storage/Network/USB) 422 having a second DMA interface connecting to the third interface 408. Please note that there can be more functional modules attached to the memory channel bridge to access the memory module depending on application needs. In one embodiment, as shown in FIG. 4C, the first functional module is a memory module 430; and the memory channel bridge further comprising a memory controller 431 coupled to the arbiter 407 and the first interface 404 to control the memory module.

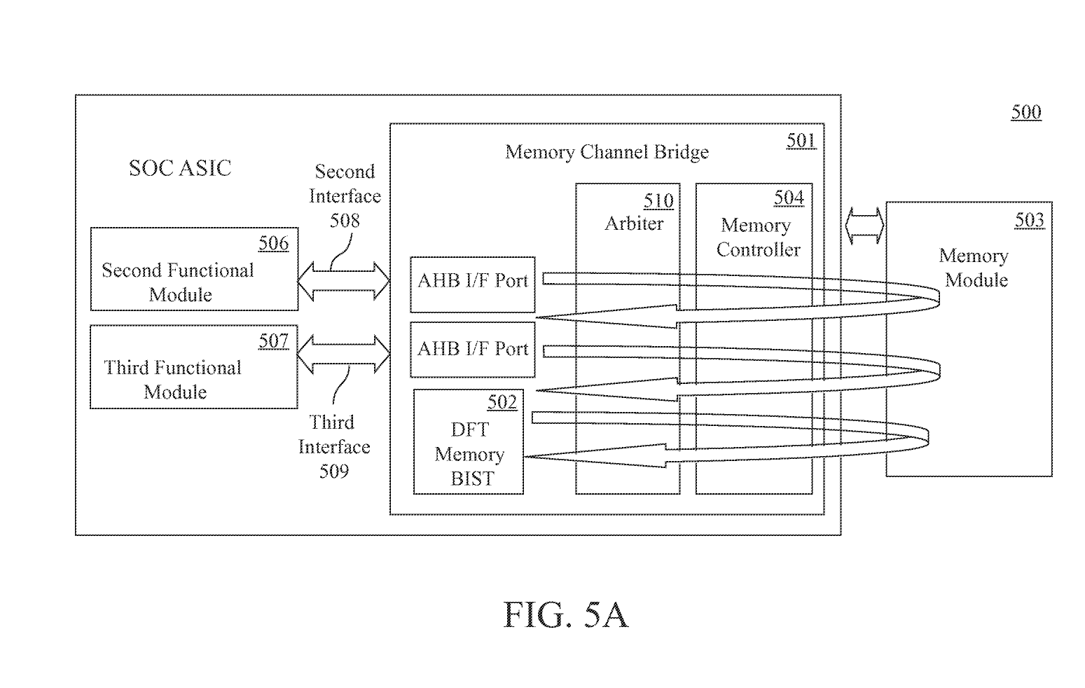

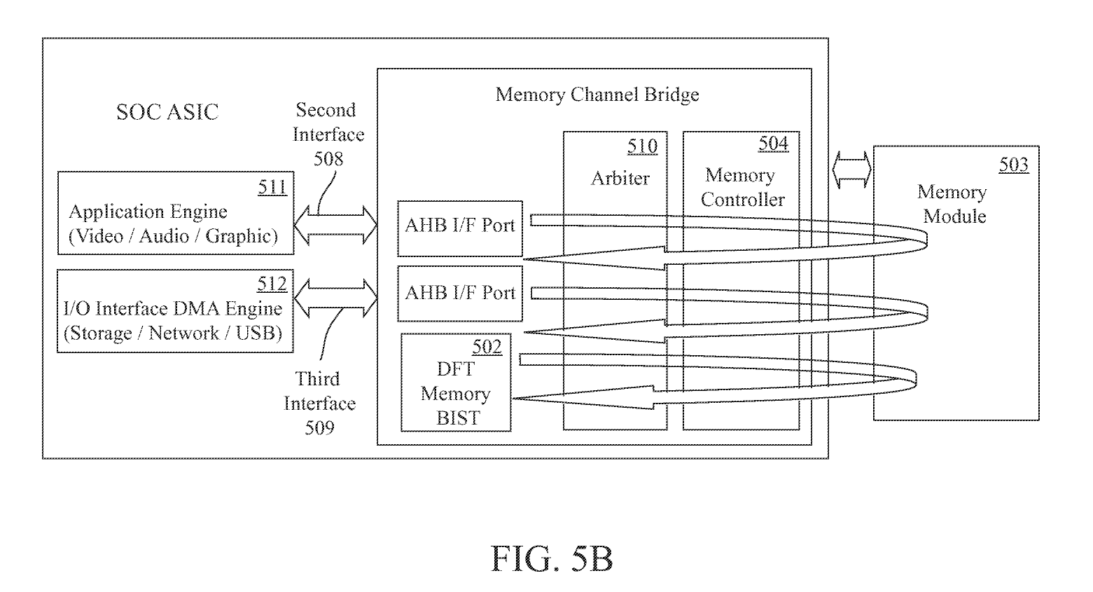

Please refer to FIG. 5A which illustrates a diagram 500 of SOC comprising a memory channel bridge 501 according to one embodiment of current invention. As shown in FIG. 5A, a BIST module 502 and a second functional module 506 are connected to an arbiter 510 to access a memory module 503 through a memory controller 504. Depending on the type of the memory module, the memory controller 504 can include a physical layer to connect to the memory module which is made of DDR DRAM or alike devices. In one embodiment, The system-on-chip further comprises a third functional module 507 coupled to the arbiter 510, wherein the arbiter 510 arbitrates among the BIST module 502, the second functional module 506 and the third functional module 507 to access the memory module 503, wherein the BIST module 502, the second functional module 506 and the third functional module 507 access the memory module 503 concurrently while the memory module 503 is being tested by the BIST module 502. There can be more functional modules attached to the memory channel bridge to access the memory module depending on application needs.

As shown in FIG. 5B, the second functional module is an application engine (Video/Audio/Graphic) 511 having a first DMA interface connecting to the second interface 508 and the third functional module is an I/O Interface DMA engine (Storage/Network/USB) 512 having a second DMA interface connecting to the third interface 509.

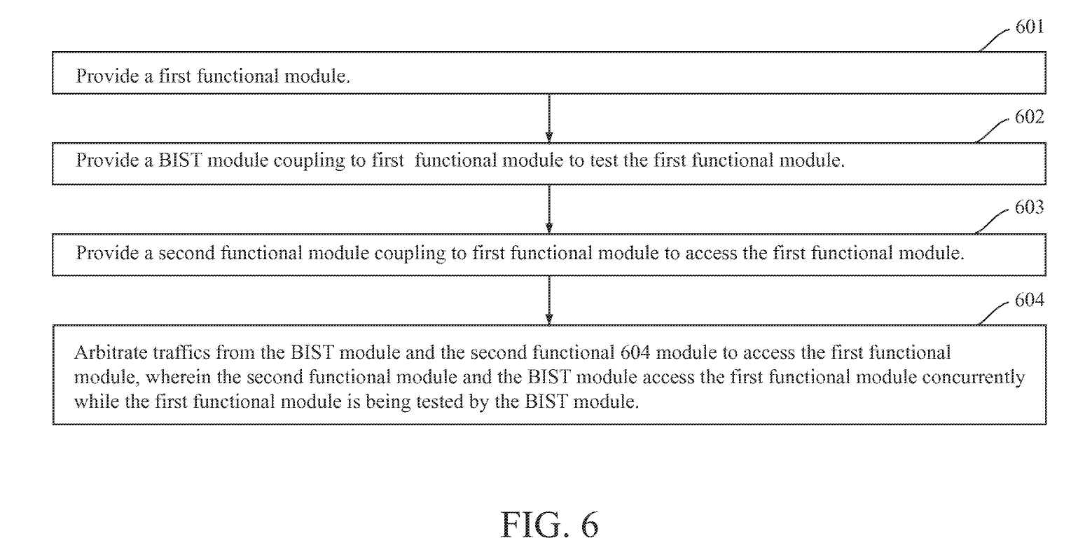

In one embodiment, FIG. 6 illustrates a flow chart of for performing a DFT test. First, a first functional module is provided as shown in step 601; a BIST module coupling to first functional module to test the first functional module is provided as shown in step 602;

and a second functional module coupling to first functional module to access the first functional module is provided as shown in step 603. Then, as shown in step 604. the traffics from the BIST module and the second functional module to access the first functional module are arbitrated, wherein the second functional module and the BIST module access the first functional module concurrently while the first functional module is being tested by the BIST module

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the claims appended hereto and their equivalents.

What is claimed is:

1. A channel bridge, comprising:
a first interface, for connecting to a first functional module;
a BIST module coupling to the first interface, for testing the first functional module;
a second interface, for connecting to a second functional module; and
an arbiter coupled to the BIST module and the second interface, for arbitrating between the BIST module and the second functional module to access the first functional module;
wherein the second functional module and the BIST module access the first functional module concurrently while the first functional module is being tested by the BIST module.

2. The channel bridge according to claim 1, wherein the first functional module comprises a memory module and a memory controller to control the memory module.

3. The channel bridge according to claim 1, wherein the first functional module is a memory module, further comprising a memory controller coupled to the arbiter and the first interface to control the memory module, wherein the second functional module and the BIST module access the first functional module through the memory controller concurrently while the first functional module is being tested by the BIST module.

4. The channel bridge according to claim 3, wherein the memory module comprises DDR DRAM devices.

5. The channel bridge according to claim 1, further comprising a third interface for connecting to a third functional module, wherein the arbiter is further coupled to the third interface to arbitrate among the BIST module, the second functional module and the third functional module to access the first functional module, wherein the BIST module, the second functional module and the third functional module access the first functional module concurrently while the first functional module is being tested by the BIST module.

6. The channel bridge according to claim 3, wherein the second functional module is a graphic engine having a DMA interface connecting to the second interface.

7. The channel bridge according to claim 3, wherein the second functional module is a network controller having a DMA interface connecting to the second interface.

8. The channel bridge according to claim 5, wherein the second functional module is a graphic engine having a first DMA interface connecting to the second interface and the third functional module is a network controller having a second DMA interface connecting to the third interface.

9. A system-on-chip (SOC), comprising:
a first interface, for connecting to a memory module;
a BIST module coupling to the first interface, for testing the memory module a second functional module;
an arbiter coupled to the BIST module and the second functional module, for arbitrating between the BIST module and the second functional module to access the memory module; and
a memory controller coupled to the arbiter and the first interface, for controlling the memory module;
wherein the BIST module and the second functional module access the memory module through the arbiter and the memory controller concurrently while the memory module is being tested by the BIST module.

10. The system-on-chip according to claim 9, wherein the memory module comprises DDR DRAM devices.

11. The system-on-chip according to claim 9, wherein the second functional module is a graphic engine connecting to the arbiter.

12. The system-on-chip according to claim 9 wherein the second functional module is a network controller connecting to the arbiter.

13. The system-on-chip according to claim 9, further comprising a third functional module coupled to the arbiter, wherein the arbiter arbitrates among the BIST module, the second functional module and the third functional module to access the memory module, wherein the BIST module, the second functional module and the third functional module access the memory module concurrently while the memory module is being tested by the BIST module.

14. The system-on-chip according to claim 13, wherein the second functional module is a graphic engine and the third functional module is a network controller.

15. A method of performing a DFT test, comprising the steps of:
providing a first functional module;
providing a BIST module coupling to first functional module to test the first functional module;
providing a second functional module coupling to first functional module to access the first functional module; and
arbitrating traffics from the BIST module and the second functional module to access the first functional module, wherein the second functional module and the BIST module access the first functional module concurrently while the first functional module is being tested by the BIST module.

16. The method of performing a DFT test according to claim 15, wherein the first functional module comprises a memory module and a memory controller to control the memory module.

17. The method of performing a DFT test according to claim 15, wherein the first functional module is a memory module.

18. The method of performing a DFT test according to claim 17, wherein the memory module comprises DDR DRAM devices.
